(19) United States
(12) Patent Application Publication
(10) Pub. No.: US 2020/0021294 A1
(43) Pub. Date: Jan. 16, 2020

(54) PIEZOELECTRIC DEVICE

(71) Applicant: NIHON DEMPA KOGYO CO., LTD., Tokyo (JP)

(72) Inventors: KUNIO HAMAGUCHI, Saitama (JP); Hideryo MATSUDO, Saitama (JP)

(73) Assignee: NIHON DEMPA KOGYO CO., LTD., Tokyo (JP)

(21) Appl. No.: 16/509,501

(22) Filed: Jul. 12, 2019

(30) Foreign Application Priority Data
Jul. 13, 2018 (JP) 2018-133400

(51) Int. Cl. H03L 1/02; H03H 9/08; H03H 9/15

(52) U.S. Cl. CPC H03L 1/028; H03H 9/15; H03H 9/08

(57) ABSTRACT

A piezoelectric device includes a piezoelectric element unit, a quartz glass, and a signal transmitting unit. The piezoelectric element unit includes a container and a piezoelectric piece sealed in the container. The quartz glass container contains the piezoelectric element unit. The signal transmitting unit transmits and receives an electric signal between the piezoelectric element unit and outside of the quartz glass container.

### CROSS-REFERENCE TO RELATED APPLICATIONS

This application claims the priority benefit of Japanese Patent Application No. 2018-133400, filed on Jul. 13, 2018. The entirety of the above-mentioned patent application is hereby incorporated by reference herein and made a part of this specification.

### TECHNICAL FIELD

This disclosure relates to a piezoelectric device having a feature in a container.

### DESCRIPTION OF THE RELATED ART

Various kinds of piezoelectric devices, typified by, for example, a crystal resonator, a crystal controlled oscillator, and a crystal filter, are heavily used in order to select and control frequency. Since these piezoelectric devices have frequency/temperature characteristics, the effort to reduce a temperature dependence of frequency has been conventionally spent. As one of the examples, there is, what is called, a TCXO, a temperature compensation type crystal controlled oscillator. As another example, there is, what is called, an oven-controlled crystal oscillator (OCXO), which uses a crystal element referred to as a twice-rotated cut, such as an SC cut.

In the case of the temperature compensation type crystal controlled oscillator, there lies a problem that, for example, measurements and preparations of an integrated circuit in advance are complicated, such as it is necessary to measure a temperature characteristic of a crystal resonator itself in advance, and it is necessary to have an integrated circuit that can store information for compensating the measured temperature characteristic and that is for performing the compensation process when the crystal controlled oscillator is used.

In the case of the oven-controlled crystal oscillator, a device configuration is difficult, for example, that it is necessary to have an oven with a relatively high temperature, such as 80° C. Moreover, it is actually difficult to reduce a temperature change of the oven with respect to, for example, an ambient temperature change, itself.

A need thus exists for a piezoelectric device which is not susceptible to the drawback mentioned above.

### SUMMARY

According to an aspect of this disclosure, there is provided a piezoelectric device that includes a piezoelectric element unit, a quartz glass container, and a signal transmitting unit. The piezoelectric element unit includes a container and a piezoelectric piece sealed in the container. The quartz glass container contains the piezoelectric element unit. The signal transmitting unit transmits and receives an electric signal between the piezoelectric element unit and outside of the quartz glass container.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a drawing describing a piezoelectric device 10 in a first embodiment.

FIG. 2 is a drawing describing a piezoelectric device 20 in a second embodiment.

FIG. 3 is a drawing describing a piezoelectric device 30 in a third embodiment.

FIG. 4 is a drawing describing a piezoelectric device 40 in a fourth embodiment.

FIG. 5 is a drawing describing a piezoelectric device 50 in a fifth embodiment.

FIG. 6 is a drawing describing a piezoelectric device 60 in a sixth embodiment.

FIG. 7 is a drawing describing a piezoelectric device 70 in a seventh embodiment.

FIG. 8 is a drawing describing a piezoelectric device 80 in an eighth embodiment.

FIG. 9 is a drawing describing a sealing structural example of a quartz glass container.

FIG. 10 is a drawing describing a piezoelectric device 90 in a ninth embodiment.

### DESCRIPTION OF EMBODIMENTS

The following describes embodiments of a piezoelectric device according to this application with reference to the drawings. Each drawing used in the descriptions is merely illustrated schematically for understanding the disclosure. In each drawing used in the descriptions, like reference numerals designate corresponding or identical elements, and therefore such elements will not be further elaborated here in some cases. Shapes, dimensions, materials, and similar factor described in the following embodiments are merely preferable examples within the scope of the disclosure. Therefore, the disclosure of the application is not limited to only the following embodiments.

### 1. First Embodiment

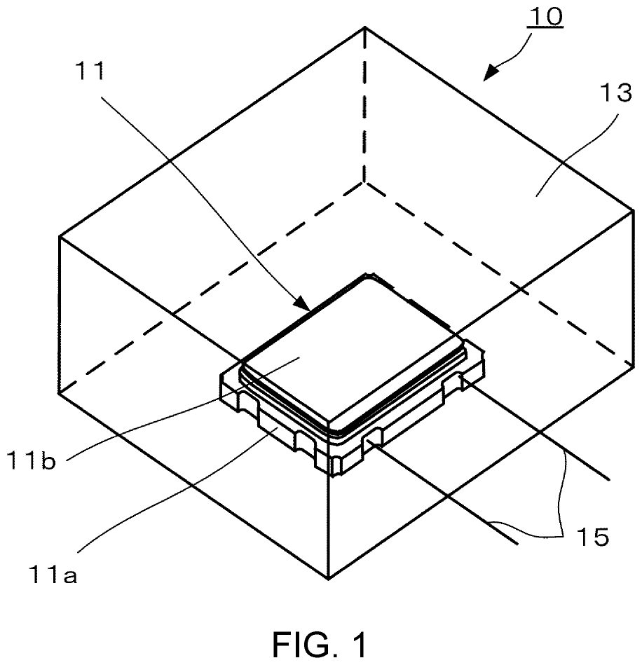

FIG. 1 is a perspective view describing a piezoelectric device 10 in a first embodiment. This piezoelectric device 10 includes a piezoelectric element unit 11 in which a piezoelectric piece is sealed in a container, a quartz glass container 13 contains this piezoelectric element unit 11, and a signal transmitting unit 15 that transmits and receives an electric signal between the piezoelectric element unit 11 and outside of the quartz glass container 13.

The piezoelectric element unit 11 of this case is a well-known crystal resonator that is a completed product including a ceramic container 11a having a depressed portion (not illustrated) that contains a crystal element (not illustrated), a lid member 11b made of a metal that is seam welded in this container 11a, and the crystal element mounted inside the above-described depressed portion. The quartz glass container 13 is made by forming the quartz glass into a box shape.

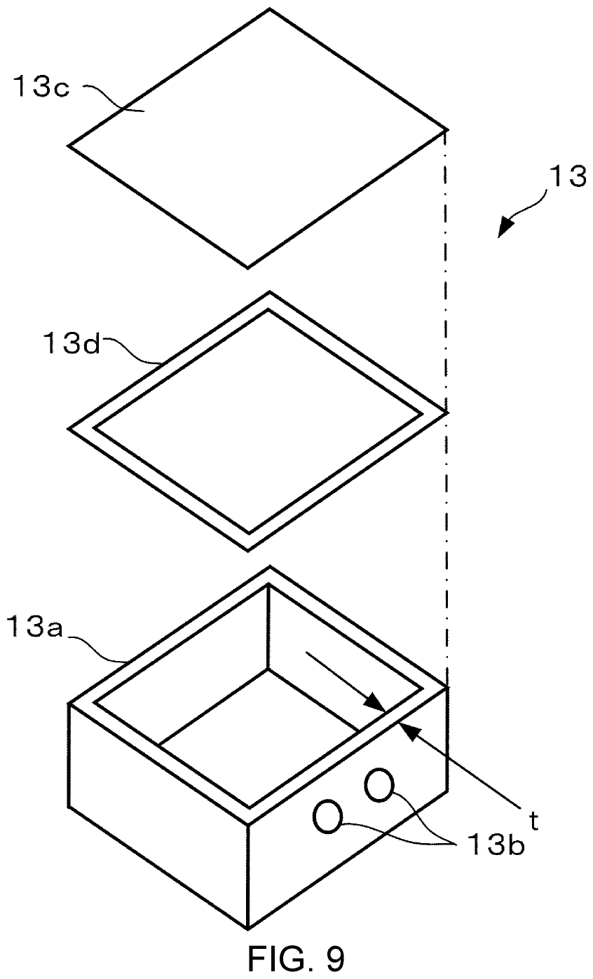

A specific example of the quartz glass container 13 has walls and a bottom having any preferred thickness t as illustrated in, for example, FIG. 9, and includes a box body 13a made of quartz glass with an upper portion opened, hole portions 13b disposed on, for example, a sidewall of this box body 13a, a lid body 13c having any preferred thickness that covers an opening of the box body 13a, and a joining member 13d that joins the box body 13a and the lid body 13c. The hole portions 13b are for installing, for example, an electric wire as the signal transmitting unit 15. The lid body 13c is also preferred to be made of quartz glass.

After the piezoelectric element unit 11 is put inside the box body 13a, the wiring as the signal transmitting unit is passed through the hole portion 13b to guide the wiring to the outside of the box body 13a. Then, the lid body 13c is joined to the box body 13a with the joining member 13d, and an appropriate filler is filled in the hole portions 13b. Thus, the piezoelectric device 10 that houses the piezoelectric element unit 11 in the quartz glass container 13 is completed. As the joining member 13d, for example, an adhesive, a low melting point glass, a brazing material, or any preferred material, such as a quartz glass can be used, but it is preferred to be the one with heat insulating properties as high as possible. As the filler for the hole portions 13b, anything preferred, such as a resin and a glass, can be used. The filler is also preferred to have high heat insulating properties, such as a quartz glass.

In the case of this example, the electric wire as the signal transmitting unit 15 has its one end connected to a crystal terminal of the piezoelectric element unit 11 and the other end connected to, for example, an oscillator circuit (not illustrated) outside the quartz glass container.

An atmosphere in a space configured of the box body 13a and the lid body 13c may be an atmospheric air or an inert atmosphere, such as a nitrogen atmosphere, or may be a vacuum atmosphere. Taking the heat insulating properties into consideration, the vacuum atmosphere is preferred. However, in order to ensure the vacuum atmosphere and the inert atmosphere, it is necessary to pay attention so as to ensure air tightness of the joining portions and the hole portions. Nonetheless, the vacuum of the space is only necessary to be low vacuum to the extent that the heat insulating properties for the piezoelectric element unit can be enhanced, therefore, the degree of difficulty of air tightness is not that high.

In the case of the piezoelectric device 10 in this first embodiment, the piezoelectric element unit 11 can be shielded from an external atmosphere with the quartz glass container 13. Since the quartz glass is excellent in heat insulating properties, effects with which the piezoelectric element unit 11 is less likely to be susceptible to an external temperature variation can be expected compared with a case where the quartz glass container is not used. As the quartz glass, an opaque quartz glass is more preferred than a transparent quartz glass.

### 2. Second Embodiment

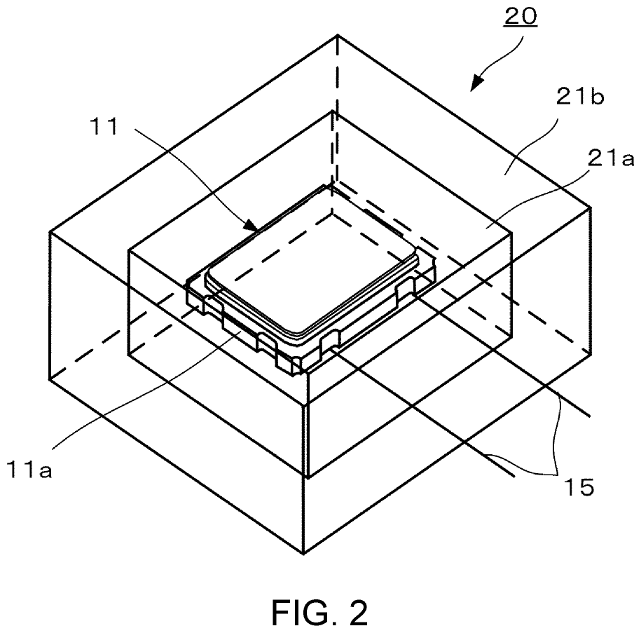

While in the case of the piezoelectric device 10 in the first embodiment, the quartz glass container 13 has a single layer, the quartz glass container may have a multiple layered structure having double layers or more. This second embodiment is such an example. FIG. 2 is a perspective view illustrating a piezoelectric device 20 in this second embodiment.

The piezoelectric element unit 11 is contained in a first container 21a made of quartz glass, and this first container 21a made of quartz glass is contained in a second container 21b made of quartz glass larger than the first container 21a. The signal transmitting unit 15 may be, for example, an electric wire similarly to the first embodiment.

In the case of the piezoelectric device 20 in this second embodiment, since the quartz glass container is double layered, the heat insulating properties are further more enhanced than the case of the first embodiment. Triple layers or more further enhances the heat insulating properties. It is more preferred if powders or wool made of quartz glass described in an eighth embodiment described later is filled within each of the quartz glass containers that are multiply layered.

### 3. Third Embodiment

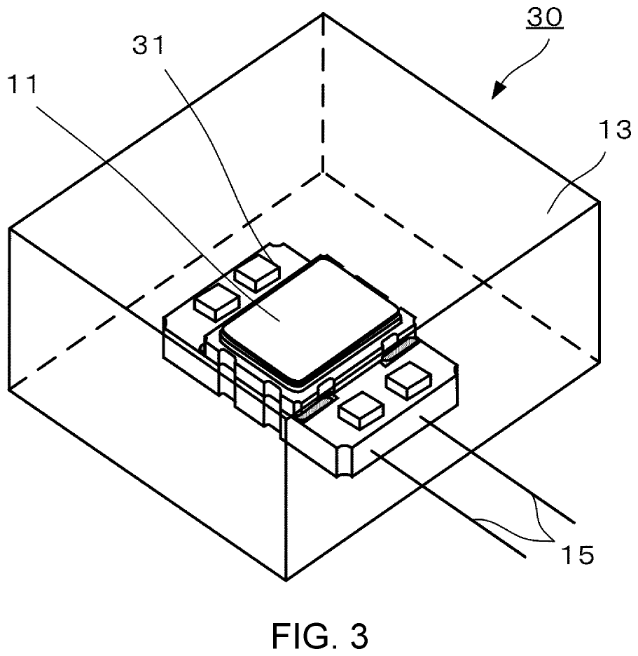

While in the case of the piezoelectric device 10 in the first embodiment, only the piezoelectric element unit is installed inside the quartz glass container 13, other configuration components, such as an oscillator circuit, may be installed inside the quartz glass container. This third embodiment is such an example. FIG. 3 is a perspective view illustrating a piezoelectric device 30 in this third embodiment.

Inside the quartz glass container 13, an oscillator circuit 31 is also contained together with the piezoelectric element unit 11. This ensures causing a temperature environment of the oscillator circuit 31 itself to be similar to that of the piezoelectric element unit 11, and therefore, it is considered to be less likely to susceptible to an external temperature change. In the case of this example, an electric wire as the signal transmitting unit 15 has its one end connected to a power supply terminal and an oscillation output terminal of the oscillator circuit 31 and the other end connected to, for example, a power source disposed outside of the quartz glass container 13 and an external circuit that uses an oscillation signal.

### 4. Fourth Embodiment

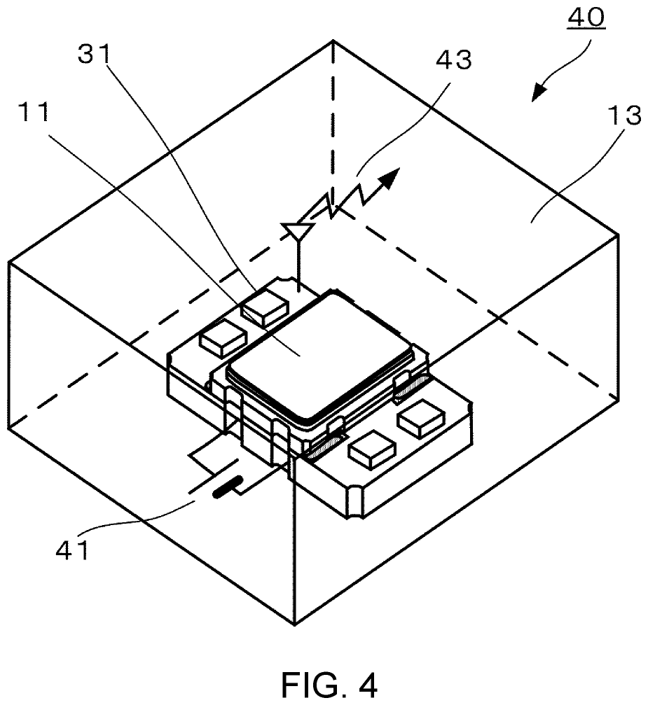

FIG. 4 is a perspective view illustrating a piezoelectric device 40 in a fourth embodiment. The piezoelectric device 40 in this fourth embodiment is an example in which the piezoelectric element unit 11, the oscillator circuit 31, a power source 41, and a wireless communicating unit 43 as a signal transmitting unit are contained in the quartz glass container 13.

The case of this fourth embodiment, since the signal transmitting unit that physically exists, such as wiring, can be eliminated, the air tightness of the quartz glass container can be expected to be enhanced more than those of the above-described first to third embodiments.

### 5. Fifth Embodiment

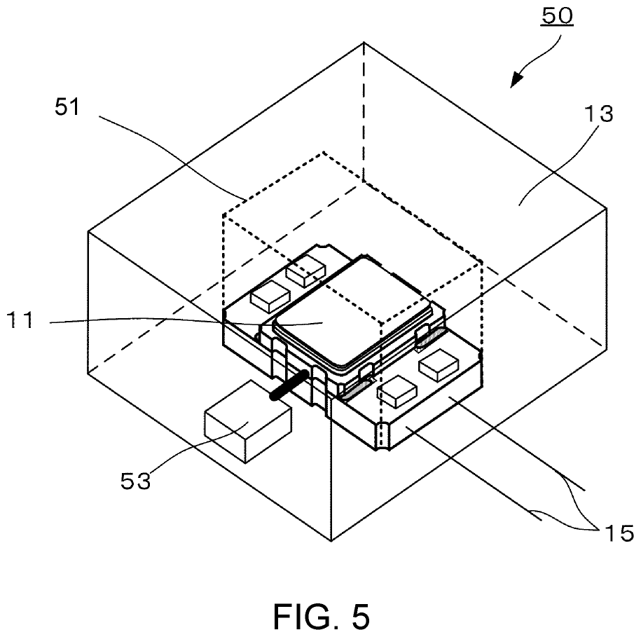

FIG. 5 is a perspective view illustrating a piezoelectric device 50 in a fifth embodiment. The piezoelectric device 50 in this fifth embodiment is a piezoelectric device in which an oven-controlled oscillator 51 that is a completed product is installed within the quartz glass container 13. A power source 53 of the oven-controlled oscillator may be contained inside the quartz glass container 13.

In the case of this fifth embodiment, since the oven-controlled oscillator whose temperature is stabilized is housed within the quartz glass container, an influence of a temperature change outside the oven-controlled oscillator can be reduced compared with the case otherwise, therefore, an improved stability of oscillation output can be expected.

### 6. Sixth Embodiment

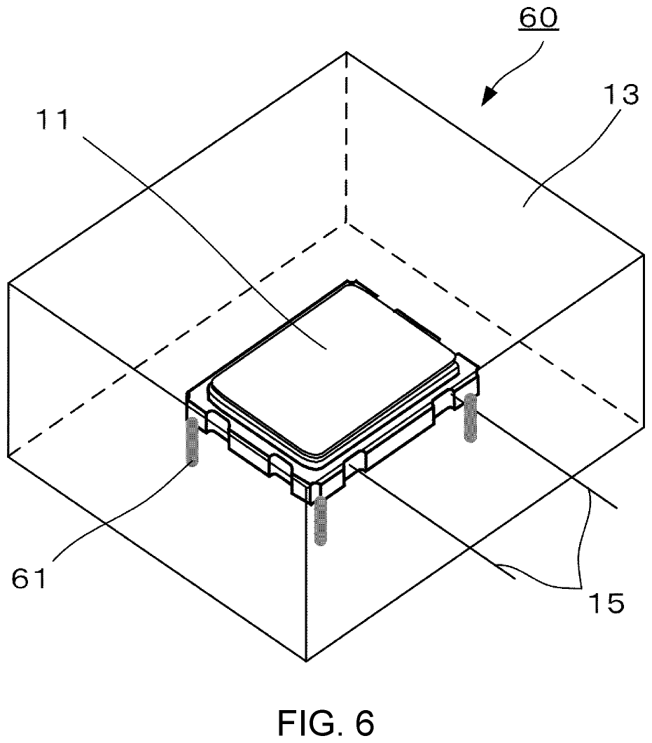

In each of the above-described embodiments, no specific structure has been illustrated to install the piezoelectric element unit 11 inside the quartz glass container 13. However, it is preferred that the piezoelectric element unit 11 is away from the wall rather than being in a state of contacting the wall of the quartz glass container 13, and is secured via a heat insulating member. This sixth embodiment is such an example. FIG. 6 is a perspective view illustrating a piezoelectric device 60 in this sixth embodiment.

The piezoelectric device 60 in this sixth embodiment has the piezoelectric element unit 11 secured to the quartz glass container 13 via a heat insulating member 61. As the heat insulating member 61, a pillar-shaped body is used in this example case. As the heat insulating member 61 in the pillar-shaped body, for example, a pillar-shaped body made of resin and a pillar-shaped body made of wood can be included. Apparently, the heat insulating member 61 is not necessarily in a pillar-shaped body, and may be in any preferred shape, such as in a spherical shape.

### 7. Seventh Embodiment

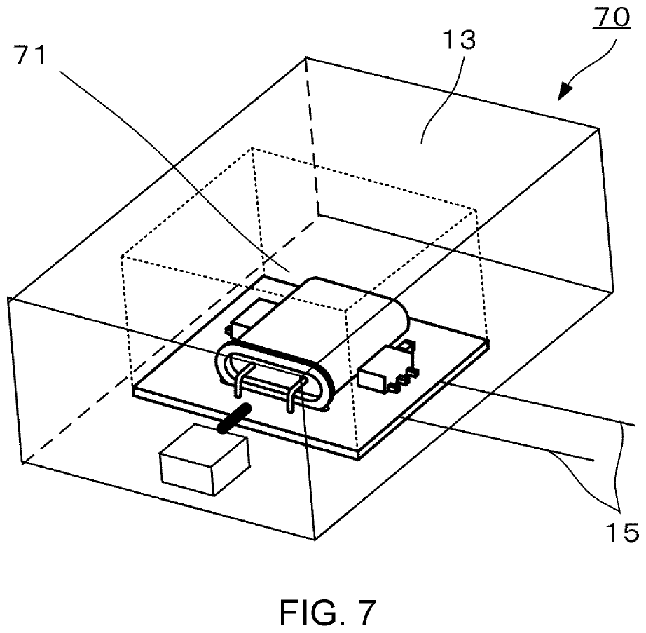

While in each of the above-described embodiments, the piezoelectric element unit 11 is the one that uses a ceramic container, the piezoelectric element unit is not limited to the ceramic container one. This seventh embodiment is such an example. FIG. 7 is a perspective view illustrating a piezoelectric device 70 in this seventh embodiment.

The piezoelectric device 70 in this seventh embodiment is an example in which a crystal element (not illustrated) is contained in a container made of a base, which uses a glass hermetic seal, and a cap made of a metal as a piezoelectric element unit 71. Moreover, it is in a form of an oven-controlled oscillator and it is installed in the quartz glass container 13.

### 8. Eighth Embodiment

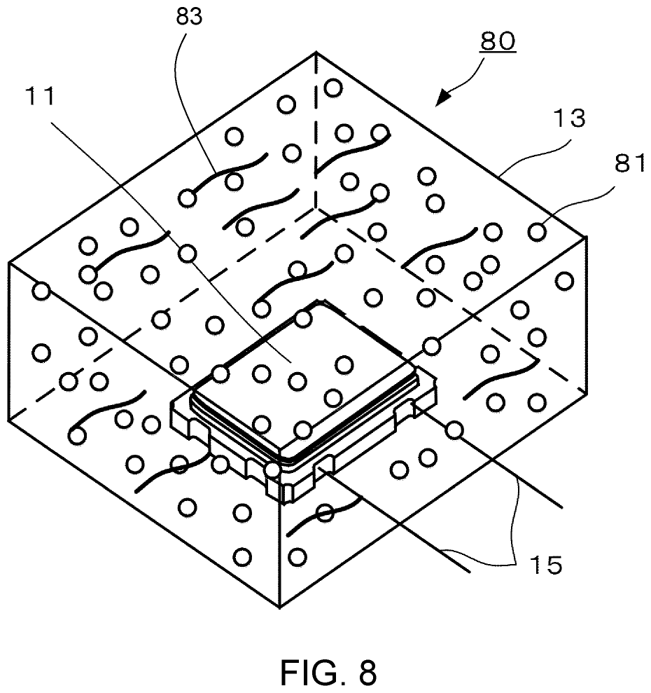

FIG. 8 is a perspective view illustrating a piezoelectric device 80 in an eighth embodiment. The piezoelectric device 80 in this eighth embodiment is an example in which powders 81 made of quartz glass and/or wool 83 made of quartz glass is filled in a space in the quartz glass container 13. That is, it is an example in which both or one of the powders 81 made of quartz glass and/or the wool 83 made of quartz glass may be filled. When the powders are microparticles, it may be any of relatively large granular matters. In the case of this eighth embodiment, the piezoelectric element unit 11 can be disposed in a state of floating in the quartz glass container 13, and moreover, can be disposed without mediating an air layer, and therefore, it is considered preferable to ensure heat insulating properties. Especially, filling the wool made of quartz glass is considered to enhance the effects.

### 9. Ninth Embodiment

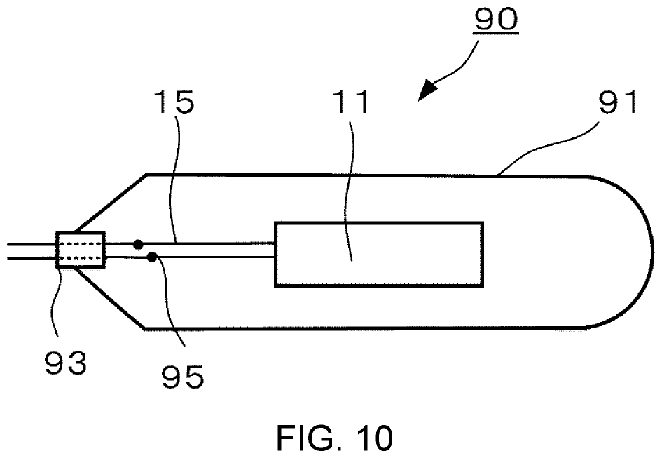

While in each of the above-described embodiments, examples in which the quartz glass container is in a box shape has been described, the shape of the quartz glass container is not limited to this. FIG. 10 is such an example, and is a perspective view illustrating a piezoelectric device 90 in the ninth embodiment. In the piezoelectric device 90 in this ninth embodiment, the quartz glass container is configured of a quartz glass pipe 91. When the quartz glass pipe 91 is used, an airtight structure of a portion from which the signal transmitting unit 15 is extracted from the quartz glass pipe 91 can be configured using a known airtight seal structure 93, and therefore, it is preferred when it is desired to make an inside of the container made of the quartz glass pipe a vacuum atmosphere. In FIG. 10, a reference numeral 95 indicates a connecting position between a cable core of the airtight seal structure 93 and the signal transmitting unit 15.

While each of the embodiments of this disclosure has been described above, this disclosure is not limited to the above-described examples. For example, the disclosure may be in a configuration in which any of the first to the ninth embodiments are preferably combined. The portions described as the quartz glass above may be a transparent quartz glass or an opaque quartz glass.

In order to solve above problems, the inventor related to this application paid attention to high heat insulating properties of a quartz glass. Furthermore, the inventor focused attention on the fact that an opaque quartz glass exhibits high heat insulating properties compared with a transparent quartz glass. It is described in Journal of Advanced Science, Vol. 11, No. 4, 1999, that the transparent quartz glass and the opaque quartz glass are excellent in heat insulating properties.

Meanwhile, the piezoelectric device generally needs to have an inside of a container stably maintained to have an inert gas atmosphere or a vacuum atmosphere for a long period of time. However, when an air tight container is formed of a quartz glass itself, there also arises a problem that achieving a sealing technique that ensures the above-described air tightness at a low price and reliably accompanies with a great difficulty.

Therefore, the inventor related to this application considered about exploiting the heat insulating properties of the quartz glass by using various kinds of conventionally known piezoelectric element unit that are completed as the piezoelectric element units themselves, and housing the completed piezoelectric element unit in a quartz glass container.

Here, the piezoelectric element unit is, for example, a crystal resonator, a crystal controlled oscillator, and a crystal filter that are completed products. Specifically, the piezoelectric element unit is a known one that uses, for example, a ceramic container sealed by any preferred sealing method, such as seam welding, gold tin, and low melting point glass. Also, it is not limited to a ceramic container, and a piezoelectric device may have an airtightly sealed lead type structure with a metal container. Apparently, the piezoelectric element unit may be the above-described TCXO and OCXO. This is because it is considered that applying this disclosure ensures reducing the above-described load on the TCXO and the OCXO. The piezoelectric element unit may use a piezoelectric material other than a crystal.

The quartz glass is a glass whose main component is silicon dioxide. Specifically, the quartz glass is a transparent quartz glass made by melting crystals, and an opaque quartz glass made by melting silica stones and silica sands. The opaque quartz glass is more preferred because it contains air bubbles, and therefore, has heat insulating properties higher than those of the transparent quartz glass. Also, it may be the one that is made nontransparent by roughening a surface of the transparent quartz glass with, for example, hydrogen fluoride and sandblasting so that an influence of a radiant heat from outside is reduced.

An atmosphere inside the quartz glass container may be an atmospheric air or a gaseous atmosphere having a heat conduction smaller than that of the atmospheric air, or may be a vacuum atmosphere. Also, a space other than a space for the piezoelectric element unit inside the quartz glass container may be filled with powders of quartz glass or wool made of quartz glass (quartz glass made to be cotton-like). For example, thus contriving the atmosphere inside the quartz glass container, and also, filling the powders or the wool made of quartz glass in the space inside the quartz glass container ensure further enhancing the heat insulating properties for the piezoelectric element unit.

The quartz glass container may have a multiple layered structure having double layers or more. A structure with the double layers or more ensures further enhancing heat insulating effects. Even when the quartz glass container is thus made to have the structure with the double layers or more, it is also possible to combine contriving the gaseous atmosphere of the space inside the container and using the filler, as described above.

The thicker the thickness of the quartz glass, the higher the heat insulating properties of the quartz glass container gets. Accordingly, the thickness of the quartz glass container is preferred to be as thick as it does not interfere with a design of the piezoelectric device. Specifically, there may be a case where the thickness of the quartz glass container has a several cm.

If the piezoelectric element unit is in contact with a wall of the quartz glass container, heat-shielding properties is reduced, and therefore, it is preferred to install the piezoelectric element unit within the quartz glass container in a state without contacting the walls of the quartz glass container. For example, it is preferred that the piezoelectric element unit is held floated from the quartz glass container with legs made of a material high in heat insulating properties. The wool made of quartz glass is also considered to be the material that can install the piezoelectric element unit in a state of being held floated within the quartz glass container.

With the piezoelectric device according to the embodiment, the piezoelectric element unit itself is a completed product, thereby ensuring an airtightness reliability of the piezoelectric element unit itself. This piezoelectric element unit is housed within the quartz glass container, thereby ensuring reduced influence of external heat on the piezoelectric element unit with the heat insulating effects of this quartz glass container. In view of this, it can be expected to reduce a temperature dependence of frequency of the piezoelectric device with a simple configuration.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device comprising:
a piezoelectric element unit that includes a container and a piezoelectric piece sealed in the container;
a quartz glass container, containing the piezoelectric element unit; and
a signal transmitting unit that transmits and receives an electric signal between the piezoelectric element unit and outside of the quartz glass container.

2. The piezoelectric device according to claim 1, further comprising:
an oscillator circuit for the piezoelectric element unit.

3. The piezoelectric device according to claim 2, wherein
the oscillator circuit is included inside of the quartz glass container.

4. The piezoelectric device according to claim 1, further comprising:
an oven that controls the piezoelectric element unit to be at a predetermined temperature.

5. The piezoelectric device according to claim 4, wherein
the oven is included inside of the quartz glass container.

6. The piezoelectric device according to claim 1, wherein
the quartz glass container has a multiple layered structure that has double layers or more.

7. The piezoelectric device according to claim 1, wherein
the signal transmitting unit is an electric wire disposed across inside and outside of the quartz glass container.

8. The piezoelectric device according to claim 7, wherein
the signal transmitting unit is a wireless communicating unit that is internally disposed in the quartz glass container.

9. The piezoelectric device according to claim 1, wherein
the container that seals the piezoelectric piece inside is a ceramic container.

10. The piezoelectric device according to claim 1, wherein
the container that seals the piezoelectric piece inside is a metal container.

11. The piezoelectric device according to claim 1, wherein
an atmosphere inside the quartz glass container is an atmospheric air.

12. The piezoelectric device according to claim 1, wherein
an atmosphere inside the quartz glass container is vacuum.

13. The piezoelectric device according to claim 1, wherein
a quartz glass powder is filled in a space other than a space for the piezoelectric element unit inside the quartz glass container.

14. The piezoelectric device according to claim 1, wherein
a quartz glass wool is filled in a space other than a space for the piezoelectric element unit inside the quartz glass container.

15. The piezoelectric device according to claim 1, wherein
a quartz glass of the quartz glass container is a transparent quartz glass.

16. The piezoelectric device according to claim 1, wherein
a quartz glass of the quartz glass container is an opaque quartz glass.

17. The piezoelectric device according to claim 1, wherein
the piezoelectric piece is a crystal element.
